(19) United States
(12) Patent Application Publication
(10) Pub. No.: US 2026/0213150 A1
(43) Pub. Date: Jul. 23, 2026

(54) BATTERY MANAGEMENT SYSTEM

(71) Applicants: TOYOTA JIDOSHA KABUSHIKI KAISHA, Toyota-shi (JP); KABUSHIKI KAISHA TOYOTA CHUO KENKYUSHO, Nagakute-shi (JP)

(72) Inventors: Yoshiaki KIKUCHI, Toyota-shi (JP); Ryo MANO, Nisshin-shi (JP); Hiroki TASHIRO, Nisshin-shi (JP); Yuji NISHI, Nagoya-shi (JP); Keisuke ISHIKAWA, Nagakute-shi (JP)

(73) Assignees: TOYOTA JIDOSHA KABUSHIKI KAISHA, Toyota-shi (JP); KABUSHIKI KAISHA TOYOTA CHUO KENKYUSHO, Nagakute-shi (JP)

(21) Appl. No.: 19/423,580

(22) Filed: Dec. 17, 2025

(30) Foreign Application Priority Data
Jan. 14, 2025 (JP) 2025-004729

(51) Int. Cl. H01M 4/04; G01R 19/04; G01R 19/06; G01R 31/389; H01M 10/42

(52) U.S. Cl. CPC H01M 4/0402; G01R 19/04; G01R 19/06; G01R 31/389; H01M 10/425; H01M 2010/4271

(57) ABSTRACT

A battery management system according to the present disclosure includes at least: a three-phase inverter configured to be driven by electric power from a lithium-ion secondary battery; a control unit configured to heat the lithium-ion secondary battery by supplying, to the lithium-ion secondary battery, an alternating current signal of a predetermined frequency generated by the three-phase inverter; and an impedance detection unit configured to detect, from an attenuation characteristic of a high-frequency signal in the lithium-ion secondary battery, a value of the real part of an alternating current impedance used for calculation of the amount of Li deposition. The impedance detection unit is configured to detect a peak voltage of the alternating current signal supplied from the three-phase inverter to the lithium-ion secondary battery.

### CROSS-REFERENCE TO RELATED APPLICATION

This application claims priority to Japanese Patent Application No. 2025-004729 filed on Jan. 14, 2025. The disclosure of the above-identified application, including the specification, drawings, and claims, is incorporated by reference herein in its entirety.

### BACKGROUND

### 1. Technical Field

The present disclosure relates to battery management systems.

### 2. Description of Related Art

In order to suppress deterioration of the performance of lithium-ion secondary batteries, there is a demand to suppress an increase in lithium (Li) deposited in lithium-ion secondary batteries during rapid charging etc. In recent years, techniques for detecting lithium deposition inside lithium-ion secondary batteries, such as that disclosed in Japanese Unexamined Patent Application Publication No. 2022-108602 (JP 2022-108602 A), have also been developed.

### SUMMARY

When the peak voltage of an alternating current signal supplied to a lithium-ion secondary battery for ripple heating is excessively high, lithium (Li) may be deposited in the lithium-ion secondary battery.

The present disclosure has been made in view of the above circumstances, and an object thereof is to provide a battery management system capable of detecting the peak voltage of an alternating current signal supplied to a lithium-ion secondary battery for ripple heating, namely the peak voltage that contributes to Li deposition.

A battery management system according to the present disclosure includes at least: a three-phase inverter configured to be driven by electric power from a lithium-ion secondary battery; a control unit configured to heat the lithium-ion secondary battery by supplying, to the lithium-ion secondary battery, an alternating current signal of a predetermined frequency generated by the three-phase inverter; and an impedance detection unit configured to detect, from an attenuation characteristic of a high-frequency signal in the lithium-ion secondary battery, a value of the real part of an alternating current impedance used for calculation of the amount of Li deposition. The impedance detection unit is configured to detect a peak voltage of the alternating current signal supplied from the three-phase inverter to the lithium-ion secondary battery. The battery management system according to the present disclosure can not only calculate the amount of Li deposition in the lithium-ion secondary battery, but also detect the peak voltage of the alternating current signal supplied to the lithium-ion secondary battery for ripple heating, namely the peak value that contributes to Li deposition. Furthermore, the battery management system according to the present disclosure detects the peak voltage of the alternating current signal supplied to the lithium-ion secondary battery for ripple heating by using the impedance detection unit employed for calculation of the amount of Li deposition in the lithium-ion secondary battery. Since the peak voltage of the alternating current signal supplied to the secondary battery for ripple heating can be detected without provision of an additional circuit, cost reduction and simplification can be achieved.

The present disclosure can provide a battery management system capable of detecting the peak voltage of an alternating current signal supplied to a lithium-ion secondary battery for ripple heating, namely the peak voltage that contributes to Li deposition.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a block diagram showing an example of the configuration of a battery management system according to a first embodiment;

FIG. 2 is a graph showing the relationship between the state of health (SOH) of a secondary battery and the amount of change in the real part Z of an alternating current impedance when a high-frequency signal of 1 MHz is supplied to the secondary battery;

FIG. 3 is a graph showing the relationship between the frequency of an alternating current signal supplied to the secondary battery and the real part of an alternating current impedance detected from the secondary battery;

FIG. 4 is a graph showing the relationship between the frequency of an alternating current signal supplied to the secondary battery and the real part of an alternating current impedance detected from the secondary battery;

FIG. 5 is a diagram showing a specific example of the configuration of an impedance detection unit provided in a battery management device according to the first embodiment; and

FIG. 6 is a graph showing the attenuation characteristic of a high-frequency signal supplied to the secondary battery at the time of calculation of the amount of Li deposition.

### DETAILED DESCRIPTION OF EMBODIMENTS

Hereinafter, specific embodiments of the present disclosure will be described in detail with reference to the drawings. However, the present disclosure is not limited to the embodiments described below. For the sake of clarity, the following description and drawings are simplified as appropriate.

### First Embodiment

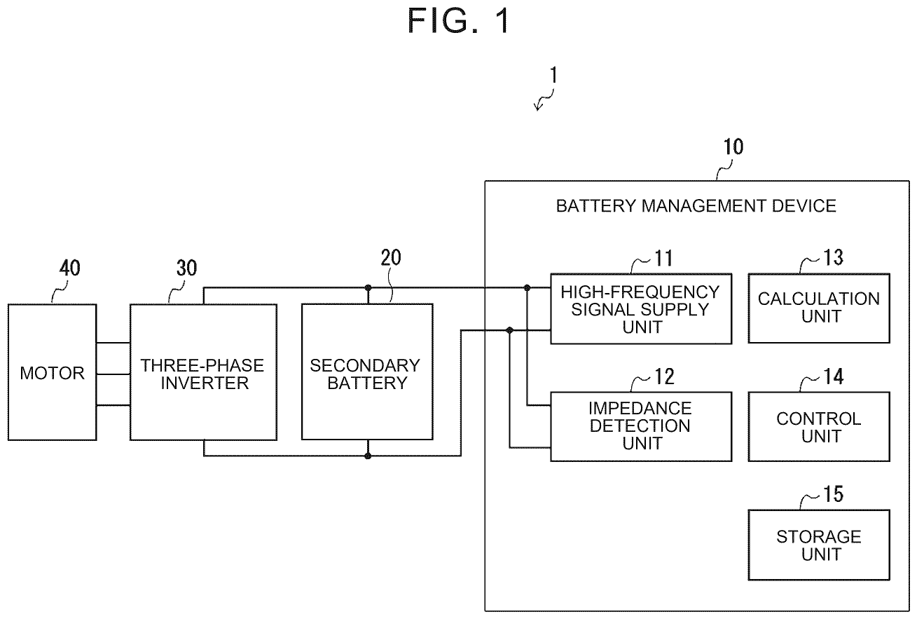

FIG. 1 is a block diagram illustrating an example of the configuration of a battery management system according to a first embodiment. As shown in FIG. 1, a battery management system 1 includes a battery management device 10, a secondary battery 20 managed by the battery management device 10, and a three-phase inverter 30 driven by the electric power from the secondary battery 20. FIG. 1 also shows a motor 40 driven by the three-phase inverter.

The secondary battery 20 is a lithium-ion secondary battery, and includes a cell stack of a plurality of stacked battery cells and a case that houses the cell stack.

Each battery cell includes a cathode, an anode, and an ion-conducting medium provided between the cathode and the anode to conduct carrier ions therebetween. A separator may further be provided between the cathode and the anode. The separator may be made of a resin such as polyethylene or polypropylene.

A cathode active material may be, for example, a sulfide containing a transition metal element or an oxide containing lithium and a transition metal element. Specific examples of the cathode active material include lithium manganese composite oxides such as those having the general formula Li₍₁₋ₓ₎MnO₂ (where 0<x<1) or Li₍₁₋ₓ₎Mn₂O₄, lithium cobalt composite oxides such as those having the general formula Li₍₁₋ₓ₎CoO₂, lithium nickel composite oxides such as those having the general formula Li₍₁₋ₓ₎NiO₂, and lithium nickel cobalt manganese composite oxides such as those having the general formula Li₍₁₋ₓ₎NiₐCo_{b}Mn_{c}O₂ (where a+b+c=1). Substances containing other elements in addition to those represented by the above general formulas may also be used as the cathode active material. A cathode current collector may be made of, for example, aluminum (Al).

An anode active material may be, for example, a composite oxide containing lithium, or a carbon material. Specific examples of the anode active material include lithium, inorganic compounds such as lithium alloys and tin compounds, carbon materials capable of storing and releasing lithium ions, composite oxides containing multiple elements, and conductive polymers. Examples of carbon materials for the anode active material include cokes, glassy carbons, graphite materials, non-graphitizable carbons, pyrolytic carbons, or carbon fibers. Graphite materials such as artificial graphite and natural graphite are preferred. Examples of composite oxides for the anode active material include lithium titanium composite oxides and lithium vanadium composite oxides. An anode current collector may be made of, for example, copper (Cu).

For example, the ion-conducting medium may be used as an electrolyte solution by dissolving a supporting salt. The supporting salt may be a lithium salt such as LiPF₆ or LiBF₄. The solvent of the electrolyte solution may be any of carbonates, esters, ethers, nitriles, furans, sulfolanes, and dioxolanes, or a mixture of two or more thereof. Examples of carbonates include cyclic carbonates such as ethylene carbonate, propylene carbonate, vinylene carbonate, butylene carbonate, and chloroethylene carbonate, and linear carbonates such as dimethyl carbonate, ethyl methyl carbonate, diethyl carbonate, ethyl-n-butyl carbonate, methyl-t-butyl carbonate, diisopropyl carbonate, and t-butyl isopropyl carbonate. Alternatively, the ion-conducting medium may be a solid ion-conducting polymer, an inorganic solid electrolyte, a composite material of an organic polymer electrolyte and an inorganic solid electrolyte, or an inorganic solid powder bound with an organic binder.

The battery management device 10 manages charging of the secondary battery 20 to be managed. For example, the battery management device 10 nondestructively detects the amount of Li deposition in the secondary battery 20 and performs feedback control of allowable charging power (upper limit of charging power) Pa for the secondary battery 20 based on the detection result.

Specifically, the battery management device 10 includes a high-frequency signal supply unit 11, an impedance detection unit 12, a calculation unit 13, a control unit 14, and a storage unit 15.

The high-frequency signal supply unit 11 supplies a high-frequency signal to the secondary battery 20. The impedance detection unit 12 detects a value of the real part Z of the alternating current impedance from the secondary battery 20 supplied with the high-frequency signal. As will be described later, the high-frequency signal supply unit 11 may be part of the impedance detection unit 12.

In the secondary battery 20, metallic Li is deposited on the electrode surfaces of the battery cells as charging is repeated. The greater the charging power applied to increase the charging speed, the more the Li deposition progresses, thereby deteriorating the state of health (SOH) of the secondary battery 20. The SOH of the secondary battery 20 is the ratio of the current capacity to the initial capacity of the secondary battery 20, the initial capacity being defined as 100%. Accordingly, it is desirable to set the allowable charging power Pa for the secondary battery 20 as high as possible, while suppressing Li deposition and enabling efficient charging in as short a charging time as possible.

When an alternating current signal (high-frequency signal) having a frequency so high that the diffusion, reaction, and migration of lithium ions in each battery cell of the secondary battery 20 cannot keep up is supplied to the secondary battery 20, the current of the high-frequency signal flows along the edges of the conductors of the battery cells due to the skin effect. In other words, the current of the high-frequency signal flows over the electrode surfaces of the battery cells, where Li deposition tends to occur, due to the skin effect. Even when metallic Li, deposited by Li deposition, becomes electrically isolated from the anode and enters a floating state, the current also flows over the metallic Li by inductive coupling and capacitive coupling. Accordingly, for example, the smaller the amount of Li deposition, the lower the electrical conductivity of the electrode surfaces of the battery cells, and thus the larger the value of the real part Z of the alternating current impedance. The larger the amount of Li deposition, the higher the electrical conductivity of the electrode surfaces of the battery cells, and thus the smaller the value of the real part Z of the alternating current impedance. Since a large amount of current is concentrated in metallic Li having high conductivity, the magnetic field varies around the Li deposition regions, thereby generating eddy currents. These eddy currents cause loss in the conductive portions of the current collecting foils and electrodes, but reduce the overall loss in the battery. Therefore, as the amount of Li deposition increases, the magnetic field variation increases, and accordingly the eddy currents increase, thereby reducing the value of the real part Z. Accordingly, the amount of Li deposition in the secondary battery 20 can be calculated from the value of the real part Z of the alternating current impedance detected from the secondary battery 20 supplied with the high-frequency signal. Once the amount of Li deposition is known, the SOH of the secondary battery 20 can also be estimated.

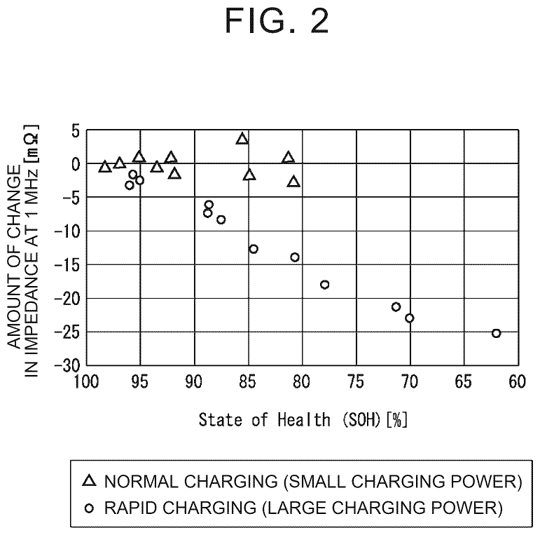

FIG. 2 is a graph showing the relationship between the SOH of the secondary battery 20 and the amount of change in the real part Z of the alternating current impedance (the difference between the detected value and the initial value) when a high-frequency signal of 1 MHz is supplied to the secondary battery 20. As indicated by triangles in FIG. 2, in the case of normal charging with small charging power, the amount of Li deposition remains small even when charging is repeated. Therefore, the amount of change in the real part Z of the alternating current impedance also remains small, even if the deterioration of the SOH progresses due to other factors (that is, the detected value of the real part Z of the alternating current impedance is kept at a high value). In contrast, as indicated by circles in FIG. 2, in the case of rapid charging with large charging power, repeated charging increases the amount of Li deposition. Accordingly, deterioration of the SOH progresses, and the amount of change in the real part Z of the alternating current impedance increases (that is, the detected value of the real part Z of the alternating current impedance decreases). When battery deterioration due to Li deposition is dominant among the factors of battery deterioration, the amount of Li deposition can be derived from the SOH. Alternatively, the SOH can be derived from the amount of Li deposition.

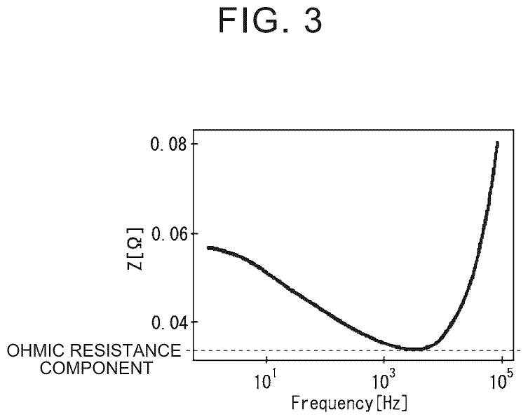

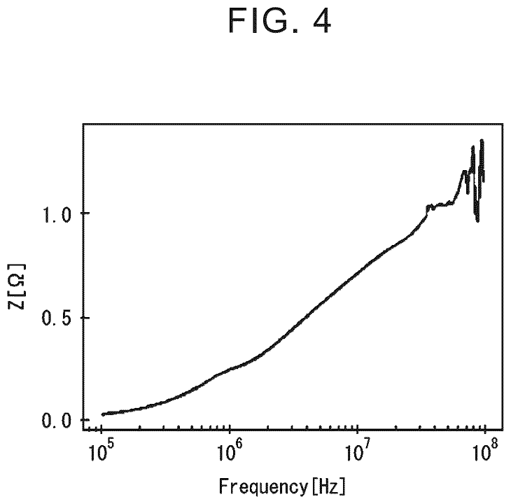

FIGS. 3 and 4 are graphs showing the relationship between the frequency of the alternating current signal supplied to the secondary battery 20 and the real part of the alternating current impedance detected from the secondary battery 20. FIG. 3 shows values of the real part Z of the alternating current impedance when alternating current signals from 1 kHz to 100 kHz are supplied to the secondary battery 20. FIG. 4 shows values of the real part Z of the alternating current impedance when alternating current signals from 100 kHz to 100 MHz are supplied to the secondary battery 20.

As shown in FIG. 3, when an alternating current signal of around 1 kHz is supplied to the secondary battery 20, the value of the real part Z of the alternating current impedance reaches a minimum value. The impedance component at this time represents the ohmic resistance component. As shown in FIGS. 3 and 4, as the frequency of the alternating current signal supplied to the secondary battery 20 increases, the current flow is concentrated on the electrode surfaces of the battery cells due to the skin effect, and therefore the value of the real part Z of the alternating current impedance increases.

Accordingly, the high-frequency signal supply unit 11 supplies to the secondary battery 20 an alternating current signal of such a high frequency (i.e., a high-frequency signal) that the value of the real part Z of the alternating current impedance that is sufficiently higher than the ohmic resistance component is detected. For example, the high-frequency signal supply unit 11 supplies a high-frequency signal of 0.1 MHz or higher to the secondary battery 20. Alternatively, the high-frequency signal supply unit 11 supplies, to the secondary battery 20, a high-frequency signal having a frequency at which, compared with the value of the real part Z of the alternating current impedance detected when a 1 kHz alternating current signal is supplied to the secondary battery 20, a value of the real part Z of the alternating current impedance that is ten times or more, due to the skin effect, is detected. In the examples in FIGS. 3 and 4, the high-frequency signal supply unit 11 supplies a high-frequency signal of 0.5 MHz or higher to the secondary battery 20. As a result, the current of the high-frequency signal flows over the electrode surfaces (Li deposition regions) of the battery cells of the secondary battery 20 due to the skin effect. Accordingly, the impedance detection unit 12 can detect the real part Z of the alternating current impedance according to the amount of Li deposition.

The calculation unit 13 calculates the amount of Li deposition in the secondary battery 20 from the value of the real part Z of the alternating current impedance detected by the impedance detection unit 12. More specifically, the calculation unit 13 calculates the amount of Li deposition in the secondary battery 20 based on the difference between the current value of the real part Z of the alternating current impedance detected by the impedance detection unit 12 and the initial value of the real part Z of the alternating current impedance of the secondary battery 20. Information on the initial value of the real part Z of the alternating current impedance of the secondary battery 20 to be managed is stored in, for example, the storage unit 15.

For example, the calculation unit 13 calculates a smaller value of the amount of Li deposition as the detected value of the real part Z of the alternating current impedance increases, and calculates a larger value of the amount of Li deposition as the detected value of the real part Z of the AC impedance decreases.

The storage unit 15 may store information on the initial values of the real part Z of the alternating current impedance of secondary batteries of each type. The storage unit 15 may also store map information representing the relationship between the difference (amount of change) between the current value (detected value) and the initial value of the real part Z of the alternating current impedance of the secondary batteries of each type, and the amount of Li deposition. This map information is, for example, information obtained in advance through experimentation, but may be updated as appropriate based on information detected from the secondary battery 20 to be managed. In this case, the calculation unit 13 extracts the amount of Li deposition corresponding to the value of the real part Z of the alternating current impedance detected by the impedance detection unit 12, from the map information stored in the storage unit 15.

The control unit 14 controls the allowable charging power Pa for the secondary battery 20 based on the amount of Li deposition calculated by the calculation unit 13. For example, when the calculated amount of Li deposition is small, the progression of Li deposition is suppressed. Therefore, the control unit 14 keeps the allowable charging power Pa at the current value or increases the allowable charging power Pa through control. The larger the calculated amount of Li deposition, the more necessary it is to suppress the progression of Li deposition. Therefore, the control unit 14 reduces the allowable charging power Pa through control. The control unit 14 may also switch the allowable charging power Pa stepwise, for example, from an initial value of 100% to 95%, 90%, and so on, according to the calculated amount of Li deposition.

The battery management device 10 according to the present disclosure can thus set the allowable charging power Pa for the secondary battery 20 as high as possible while suppressing Li deposition, thereby enabling efficient charging in as short a charging time as possible. That is, the battery management device 10 according to the present disclosure can set the allowable charging power Pa for the secondary battery 20 to an appropriate value according to the amount of Li deposition without setting it excessively low. Accordingly, efficient charging of the secondary battery 20 can be realized.

Not only when the charging power of the secondary battery 20 is too large, but also when the peak voltage of a low-frequency alternating current signal supplied to the secondary battery 20 for ripple heating is too large, Li deposition may progress in the secondary battery 20. Accordingly, the battery management device 10 according to the present disclosure has a function to detect the peak voltage of a low-frequency alternating current signal supplied to the secondary battery 20 for ripple heating, namely the peak voltage that contributes to Li deposition.

Specifically, the control unit 14 first causes the three-phase inverter 30 to generate an alternating current signal of a predetermined frequency, that is, a low frequency. The alternating current signal of the predetermined frequency generated by the three-phase inverter 30 is supplied to the secondary battery 20. As a result, the secondary battery 20 starts ripple heating. At this time, the impedance detection unit 12 detects the amplitude (i.e., peak voltage) of the alternating current signal of the predetermined frequency supplied from the three-phase inverter 30 to the secondary battery 20. The impedance detection unit 12 may detect the peak voltage of the alternating current signal of the predetermined frequency during heating of each of the battery cells constituting the secondary battery 20. Alternatively, the impedance detection unit 12 may detect the peak voltage of the alternating current signal of the predetermined frequency during heating of one or more of the battery cells constituting the secondary battery 20, and estimate the peak voltage of the alternating current signal of the predetermined frequency during heating of each of the battery cells constituting the secondary battery 20, based on the detection result.

For example, when the peak voltage of the alternating current signal of the predetermined frequency during heating of the secondary battery 20 as detected by the impedance detection unit 12 (i.e., the peak voltage of the alternating current signal of the predetermined frequency supplied to the secondary battery 20) is greater than or equal to a predetermined voltage Vth, the control unit 14 stops the heating of the secondary battery 20. Alternatively, when the peak voltage of the alternating current signal of the predetermined frequency during heating of the secondary battery 20 as detected by the impedance detection unit 12 is greater than or equal to the predetermined voltage Vth, the control unit 14 reduces the peak voltage of the alternating current signal of the predetermined frequency during heating of the secondary battery 20 by reducing the amplitude of the alternating current signal supplied to the secondary battery 20. As a result, the progression of Li deposition in the secondary battery 20 is suppressed.

### Specific Configuration Example of Impedance Detection Unit 12

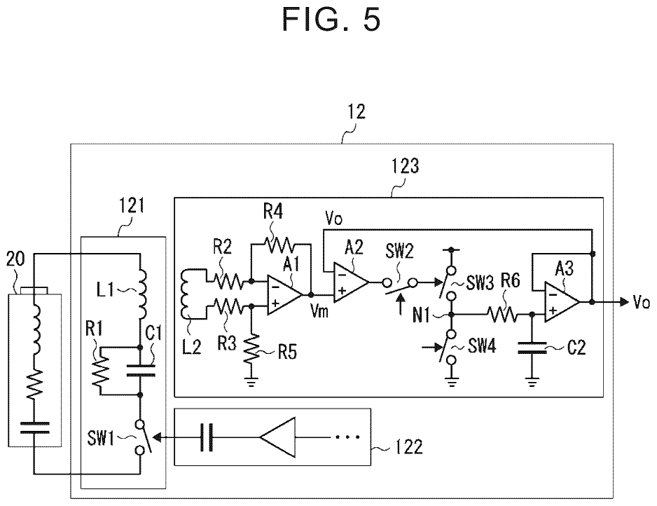

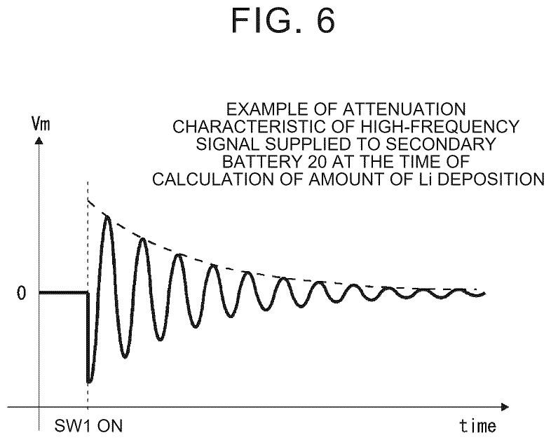

FIG. 5 shows a specific example of the configuration of the impedance detection unit 12 provided in the battery management device 10. FIG. 5 also shows the secondary battery 20. FIG. 6 is a graph showing the attenuation characteristic of the high-frequency signal supplied from the high-frequency signal supply unit 11 to the secondary battery 20 at the time of calculation of the amount of Li deposition.

As shown in FIG. 5, the impedance detection unit 12 includes a resonance circuit 121, a trigger signal output circuit 122, and a peak hold circuit 123. The impedance detection unit 12 is also referred to as impedance detection circuit. The resonance circuit 121 corresponds to the high-frequency signal supply unit 11.

The resonance circuit 121 is a circuit that resonates at a high frequency (the frequency of the high-frequency signal from the high-frequency signal supply unit 11). Specifically, the resonance circuit 121 includes an inductor L1, a capacitor C1, a resistor element R1, and a switch SW1. The resistor element R1 is provided in parallel with the capacitor C1. The inductor L1, the capacitor C1, and the switch SW1 are provided in series between the cathode and the anode of the secondary battery 20. The trigger signal output circuit 122 activates a trigger signal based on, for example, an instruction from the control unit 14 to temporarily turn on the switch SW1. When the switch SW1 is turned on, the resonance circuit 121 starts resonance at a high frequency.

During ripple heating, the alternating current signal of the predetermined frequency supplied from the three-phase inverter 30 to the secondary battery 20 is superimposed on the high-frequency resonance signal (high-frequency signal).

The peak hold circuit 123 detects, at the time of calculation of the amount of Li deposition, the value of the real part Z of the alternating current impedance of the secondary battery 20 from the attenuation characteristic of the high-frequency signal supplied to the secondary battery 20. The peak hold circuit 123 also detects, during ripple heating, the peak voltage of the alternating current signal of the predetermined frequency supplied from the three-phase inverter 30 to the secondary battery 20.

Specifically, the peak hold circuit 123 includes an inductor L2, resistor elements R2 to R6, amplifiers A1 to A3, and switches SW2 to SW4. The inductor L2 is magnetically coupled to the inductor L1 and receives the alternating current signal flowing through the inductor L1. The resistor element R2 is provided between one end of the inductor L2 and the inverting input terminal of the amplifier A1. The resistor element R3 is provided between the other end of the inductor L2 and the non-inverting input terminal of the amplifier A1. The resistor element R4 is provided between the output terminal and the inverting input terminal of the amplifier A1. The resistor element R5 is provided between the non-inverting input terminal of the amplifier A1 and the ground. The amplifier A1 amplifies the alternating current signal received by the inductor L2 from the inductor L1 and outputs the amplified signal as an output voltage Vm.

The amplifier A2 compares the output voltage Vm of the amplifier A1 (the amplified alternating current signal) with the output voltage Vo of the amplifier A3 (the output voltage of the peak hold circuit 123), and outputs the comparison result. For example, the amplifier A2 outputs an L-level comparison result when the output voltage Vm of the amplifier A1 is less than the output voltage Vo of the amplifier A3, and outputs an H-level comparison result when the output voltage Vm of the amplifier A1 is greater than or equal to the output voltage Vo of the amplifier A3.

The switch SW2 is provided between the output terminal of the amplifier A2 and the control terminal of the switch SW3, and is controlled to be off at initialization and on otherwise. However, when signals of a plurality of different frequencies are input during different periods, and it is desired to acquire the amplitude of the alternating current signal of a certain frequency alone, the switch SW2 may be controlled to be on only during the period in which the alternating current signal of the certain frequency is input, and off otherwise.

The switch SW3 is provided between a power supply voltage terminal to which a power supply voltage is supplied and a node N1. The switch SW4 is provided between the node N1 and the ground. The resistor element R6 is provided between the node N1 and the non-inverting input terminal of the amplifier A3. The output terminal and the inverting input terminal of the amplifier A3 are connected to each other. A capacitor C2 is provided between the non-inverting input terminal of the amplifier A3 and the ground. The switch SW3 is turned off when the L-level comparison result from the amplifier A2 is supplied via the switch SW2, and is turned on when the H-level comparison result from the amplifier A2 is supplied via the switch SW2. The switch SW4 is turned on when the charge stored in the capacitor C2 is released to the ground at initialization, and is controlled to be off otherwise.

For example, when the output voltage Vm of the amplifier A1 is less than the output voltage Vo of the amplifier A3, the switch SW3 remains off, and therefore, no additional charge is stored in the capacitor C2. Accordingly, the amplifier A3 keeps the output voltage Vo at the current value. On the other hand, when the output voltage Vm of the amplifier A1 is greater than or equal to the output voltage Vo of the amplifier A3, the switch SW3 turns on, and therefore, additional charge corresponding to the on-period of the switch SW3 is stored in the capacitor C2. As a result, the amplifier A3 increases the output voltage Vo by a value corresponding to the increase in charge. As this process is repeated, the output voltage Vo gradually approaches the peak voltage of the alternating current signal and eventually reaches the peak voltage of the alternating current signal or a voltage corresponding thereto. In this manner, the peak hold circuit 123 detects the peak voltage (Vo) of the alternating current signal.

At the time of calculation of the amount of Li deposition, the peak hold circuit 123 detects the attenuation characteristic of the high-frequency signal, based on the peak voltages at two or more points of the high-frequency signal and the detection interval between the peak voltages. That is, the peak hold circuit 123 detects the attenuation characteristic of the high-frequency signal from the amount of change in the peak voltage Vo per unit time. Calculation of the attenuation characteristic of the high-frequency signal may be performed in the calculation unit 13. During ripple heating, the peak hold circuit 123 detects the peak voltage (Vo) of the alternating current signal of the predetermined frequency. Specifically, the peak hold circuit 123 performs back-calculation using a calculation formula of the attenuation characteristic of the high-frequency signal. In this back-calculation, a calculated value of the attenuation characteristic, a peak voltage of an arbitrary high-frequency signal, and a detection time of the peak voltage are substituted into the calculation formula. By this back-calculation, the peak hold circuit 123 calculates a value Vp obtained by superimposing, on the battery voltage of the secondary battery 20, an amplitude component of the alternating current signal of the predetermined frequency (the AC signal supplied to the secondary battery 20 for ripple heating). The impedance detection unit 12 calculates voltages Vp at a plurality of different timings by temporarily turning on the switch SW1 at the different timings, and reconstructs the waveform of the alternating current signal of the predetermined frequency using the voltages Vp. That is, the impedance detection unit 12 calculates the amplitude of the alternating current signal of the predetermined frequency supplied to the secondary battery 20 for ripple heating.

As described above, the battery management device 10 according to the present disclosure can set the allowable charging power Pa for the secondary battery 20 as high as possible while suppressing Li deposition, thereby enabling efficient charging in as short a charging time as possible. That is, the battery management device 10 according to the present disclosure can set the allowable charging power Pa for the secondary battery 20 to an appropriate value according to the amount of Li deposition without setting it excessively low. Accordingly, efficient charging of the secondary battery 20 can be realized.

In addition, the battery management device 10 according to the present disclosure can detect the peak voltage of the alternating current signal of the predetermined frequency supplied to the secondary battery 20 for ripple heating, namely the peak voltage that contributes to Li deposition. Furthermore, the battery management device 10 according to the present disclosure detects the peak voltage of the alternating current signal of the predetermined frequency supplied to the secondary battery 20 for ripple heating by using the impedance detection unit 12 employed for calculation of the amount of Li deposition in the secondary battery 20. Since the peak voltage of the alternating current signal of the predetermined frequency supplied to the secondary battery 20 for ripple heating can be detected without provision of an additional circuit, cost reduction and simplification can be achieved.

Part or all of the processes of the battery management device 10 according to the present disclosure can be implemented by causing a central processing unit (CPU) to execute a computer program.

This program includes a set of instructions (or software code) for causing a computer to perform one or more functions described in the embodiment when the program is loaded into the computer. The program may be stored in a non-transitory computer-readable medium or a tangible storage medium. Examples of the computer-readable medium or the tangible storage medium include, but are not limited to, random access memory (RAM), read-only memory (ROM), flash memory, solid-state drives (SSDs), and other memory technologies, compact disc read-only memory (CD-ROM), digital versatile discs (DVDs), Blu-ray (registered trademark) discs, and other optical disc storage, and magnetic cassettes, magnetic tape, magnetic disk storage, and other magnetic storage devices. The program may be transmitted on a transitory computer-readable medium or a communication medium. Examples of the transitory computer-readable medium or the communication medium include, but are not limited to, propagated signals in electrical, optical, acoustic, or other forms.

While the present disclosure has been described above with reference to the embodiments, the present disclosure is not limited to the above embodiments. Various modifications that will be apparent to those skilled in the art may be made to the configurations and details of the present disclosure within the scope of the present disclosure. In addition, each embodiment may be combined with other embodiments as appropriate.

What is claimed is:

1. A battery management system comprising at least:
a three-phase inverter configured to be driven by electric power from a lithium-ion secondary battery;
a control unit configured to heat the lithium-ion secondary battery by supplying, to the lithium-ion secondary battery, an alternating current signal of a predetermined frequency generated by the three-phase inverter; and
an impedance detection unit configured to detect, from an attenuation characteristic of a high-frequency signal in the lithium-ion secondary battery, a value of a real part of an alternating current impedance used for calculation of an amount of lithium deposition, wherein
the impedance detection unit is configured to detect a peak voltage of the alternating current signal supplied from the three-phase inverter to the lithium-ion secondary battery.

2. The battery management system according to claim 1, wherein the control unit is configured to stop heating of the lithium-ion secondary battery, or reduce an amplitude of the alternating current signal supplied to the lithium-ion secondary battery, when the peak voltage during the heating of the lithium-ion secondary battery as detected by the impedance detection unit is greater than or equal to a predetermined voltage.

3. The battery management system according to claim 1, wherein the high-frequency signal has a frequency of 0.1 MHz or higher.

4. The battery management system according to claim 3, wherein the high-frequency signal has a frequency at which, compared with a value of the real part of the alternating current impedance detected when a 1 kHz alternating current signal is supplied to the lithium-ion secondary battery, a value of the real part of the alternating current impedance that is ten times or more, due to a skin effect, is detected.
